(19) United States
(12) Patent Application Publication
(10) Pub. No.: US 2006/0052965 A1
(43) Pub. Date: Mar. 9, 2006

(54) Event driven testing method, system and program product

(75) Inventor: Lisa J. Nodwell, Wilmington, MA (US)

Correspondence Address: HOFFMAN, WARNICK & D'ALESSANDRO LLC, 75 STATE ST, 14TH, ALBANY, NY, 12207, US

(73) Assignee: International Business Machines Corporation, Armonk, NY (US)

(21) Appl. No.: 10/918,238

(22) Filed: Aug. 13, 2004

(51) Int. Cl. G01R 27/28; G01R 31/00; G01R 31/14

(52) U.S. Cl. 702/119

(57) ABSTRACT

Under the present invention, a scenario is compartmentalized into a series of (discrete) events. Thereafter, a test case is provided that arranges the series of events into a desired order, and specifies event information and a verification decision for each event. The verification decision expresses whether verification of the corresponding event is desired. Then, based on the test case, a performance of the desired events in the scenario can be verified. Verification of an event generally includes executing the event, and then verifying whether the event functioned as intended.

### BACKGROUND OF THE INVENTION

1. Field of the Invention

In general, the present invention relates to an event driven testing method, system and program product. Specifically, under present invention, Information Technology (IT) scenarios are compartmentalized into a series of discrete events for improved testing automation.

2. Related Art

As the use of computing technology continues to grow, applications such as Lotus Notes, which is commercially available from International Business Machines Corp. of Armonk, N.Y., are continually being expanded to provide users with additional functionality. For example, Lotus Notes not only provides electronic messaging capabilities, but it also provides other functions such as allowing users to maintain an electronic calendar and a list of contacts. One especially convenient feature is the capability to schedule a meeting with one or more other users. This capability generally involves the transmission of a meeting invitation to a list of potential attendees. Upon receipt, each attendee can accept or decline the invitation, or even suggest a different time/day.

Unfortunately, as applications such as Lotus Notes continue to advance, testing has become more difficult. Specifically, the convenient functionality provided to users such as scheduling meeting often raises a countless combination of possible events. This makes automated testing of the applications extremely difficult, especially in cases such as where meetings are allowed to repeat. In general, automated testing would test each scenario (e.g., scheduling a meeting) separately. For example, one scenario for scheduling a meeting could have the following series of events:
(1) Create meeting invitation
(2) An invitee accepts the invitation
(3) The meeting “Chair” adds an invitee to the invitation
(4) An invitee proposes a new meeting time
   In testing this scenario, it should be verified that the series of events functioned as intended. For example, to determine whether the “Create Meeting Invitation” event functioned properly, it should be verified that the meeting was added to the “Chair's” calendar, and that all invitees received the invitation. Unfortunately, for tasks such as scheduling a meeting, there are often countless combinations of events that could exist. For example, another scenario for scheduling a meeting could have the following series of events:
(1) Create meeting invitation
(2) An invitee rejects the invitation
(3) An invitee accepts the invitation
   Current testing systems are scenario driven, meaning that new test code must be written for each scenario such as those shown above. Thus, even though different scenarios might include common events completely, new test code must be written each time. This not only increases the skills required by a tester, but also requires far more code.

Therefore, what is needed is an event driven testing methodology whereby IT scenarios such as scheduling a meeting are compartmentalized into a series of events. A further need exists for such a system to then verify a performance of the scenario on an event basis.

### SUMMARY OF THE INVENTION

In general, the present invention provides an event driven testing method, system and program product. Specifically, under the present invention, a scenario is compartmentalized into a series of (discrete) events. Thereafter, a test case is provided that arranges the series of events into a desired order, and specifies event information and a verification decision for each event. The verification decision expresses whether verification of the corresponding event is desired. Then, based on the test case, a performance of the desired events in the scenario can be verified. Verification of an event generally includes executing the event, and then verifying whether the event functioned as intended.

A first aspect of the present invention provides an event driven testing method, comprising: compartmentalizing a scenario into a series of events; developing a test case for the scenario by arranging the series of events into a desired order, and by providing event information and a verification decision for each of the series of events; and verifying a performance of the series of events based on the event information and the verification decisions provided in the test case.

A second aspect of the present invention provides an event driven testing system comprising: a test case system for developing a test case for a scenario compartmentalized into a series of events by arranging the series of events into a desired order, and by providing event information and a verification decision for each of the series of events; and a verification system for verifying a performance of the series of events based on the event information and the verification decisions provided in the test case.

A third aspect of the present invention provides an event driven testing program product stored on a recordable medium, which when executed comprises: program code for developing a test case for a scenario compartmentalized into a series of events by arranging the series of events into a desired order, and by providing event information and a verification decision for each of the series of events; and program code for verifying a performance of the series of events based on the event information and the verification decisions provided in the test case.

A fourth aspect of the present invention provides a system for deploying an event driving testing application, comprising: a computer infrastructure being operable to: develop a test case for a scenario compartmentalized into a series of events by arranging the series of events into a desired order, and by providing event information and a verification decision for each of the series of events; and verify a performance of the series of events based on the event information and the verification decisions provided in the test case.

A fifth aspect of the present invention provides computer software embodied in a propagated signal for event driving testing, the computer software comprising instructions to cause a computer system to perform the following functions: developing a test case for a scenario compartmentalized into a series of events by arranging the series of events into a desired order, and by providing event information and a verification decision for each of the series of events; and verify a performance of the series of events based on the event information and the verification decisions provided in the test case.

Therefore, the present invention provides an event driven testing method, system and program product.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts a n event driven testing system according to the present invention.

FIG. 2 depicts an illustrative method flow diagram according to the present invention.

The drawings are not necessarily to scale. The drawings are merely schematic representations, not intended to portray specific parameters of the invention. The drawings are intended to depict only typical embodiments of the invention, and therefore should not be considered as limiting the scope of the invention. In the drawings, like numbering represents like elements.

### DETAILED DESCRIPTION OF THE DRAWINGS

As indicated above, the present invention provides an event driven testing method, system and program product. Specifically, under the present invention, a scenario is compartmentalized into a series of (discrete) events. Thereafter, a test case is provided that arranges the series of events into a desired order, and specifies event information and a verification decision for each event. The verification decision expresses whether verification of the corresponding event is desired. Then, based on the test case, a performance of the desired events in the scenario can be verified. Verification of an event generally includes executing the event, and then verifying whether the event functioned as intended.

It should be understood in advance, that as used herein, the term “scenario” is intended to refer to any type of task or the like that may be performed within an application. For example, a scenario could be an Information Technology (IT) scenario such as sending a meeting invitation using an electronic messaging application. Moreover, as used herein, the term “event” is intended to mean an individual activity occurring as part of a scenario. For example, possible events occurring as part of the scenario of scheduling a meeting could be “create a meeting invitation,” “accept the invitation,” “reject the invitation,” etc. Still yet it should be understood that although the present invention will be described below in conjunction with the illustrative scenario of scheduling a meeting using an electronic messaging application, the same teachings could be used in conjunction with any type of scenario and/or application.

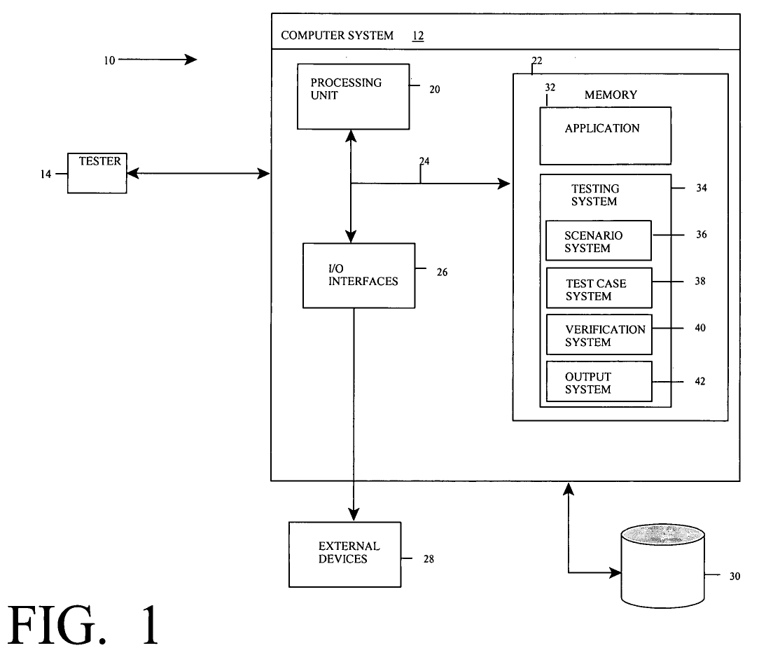

Referring now to FIG. 1, an event driven testing system 10 according to the present invention is shown. In general, system 10 allows tester 14 to test one or more scenarios within application 32 on an event basis. It should be appreciated that event driven testing under the present invention could be carried out on a stand-alone computer system 12 as shown, or over a network such as the Internet, a local area network (LAN), a wide area network (WAN), a virtual private network (VPN), etc. In the case of the latter, tester 14 could communicate with computer system 12 using another computerized device (not shown). Moreover, a direct hardwired connection (e.g., serial port), or an addressable connection with computer system 12 could be implemented. The addressable connection may utilize any combination of wireline and/or wireless transmission methods. Moreover, conventional network connectivity, such as Token Ring, Ethernet, WiFi or other conventional communications standards could be used. Still yet, connectivity could be provided by conventional IP-based protocol.

In general, computer system 12 is intended to represent any type of computerized device capable of carrying out the functions of the present invention. For example, computer system 12 could be a desktop computer, a laptop computer, a workstation, a hand held device, a client, a server, etc. In any event, computer system 12 generally comprises processing unit 20, memory 22, bus 24, input/output (I/O) interfaces 26, external devices/resources 28 and storage unit 30. Processing unit 20 may comprise a single processing unit, or be distributed across one or more processing units in one or more locations, e.g., on a client and server. Memory 22 may comprise any known type of data storage and/or transmission media, including magnetic media, optical media, random access memory (RAM), read-only memory (ROM), a data cache, a data object, etc. Moreover, similar to processing unit 20, memory 22 may reside at a single physical location, comprising one or more types of data storage, or be distributed across a plurality of physical systems in various forms.

I/O interfaces 26 may comprise any system for exchanging information to/from an external source. External devices/resources 28 may comprise any known type of external device, including speakers, a CRT, LED screen, hand-held device, keyboard, mouse, voice recognition system, speech output system, printer, monitor/display, facsimile, pager, etc. Bus 24 provides a communication link between each of the components in computer system 12 and likewise may comprise any known type of transmission link, including electrical, optical, wireless, etc.

Storage unit 30 can be any system (e.g., a database) capable of providing storage for information under the present invention. Such information could include, among other things, test cases prepared by tester 14. As such, storage unit 30 could include one or more storage devices, such as a magnetic disk drive or an optical disk drive. In another embodiment, storage unit 30 includes data distributed across, for example, a local area network (LAN), wide area network (WAN) or a storage area network (SAN) (not shown). Although not shown, additional components, such as cache memory, communication systems, system software, etc., may be incorporated into computer system 12.

Shown in memory 22 of computer system 12 is application 32 and testing system 34. As indicated above, application 32 can be any type of application now known or later developed. However, for an illustrative example, assume that application 32 is an electronic messaging application such as Lotus Notes. Further assume that tester 14 wishes to verify/test the scenario of scheduling a meeting within application 32. As mentioned above, a single scenario such as scheduling a meeting could have many different combinations of events. Under previous methods, tester 14 would be required to write large amounts of code for each scenario. However, as will be further described below, testing system 34 of the present invention verifies scenarios on an event basis, thus, obviating the need for such efforts.

Specifically, as shown, testing system 34 includes (optional) scenario system 36, test case system 38, verification system 40 and output system 42. Under the present invention, before a scenario is verified, it will be compartmentalized or broken down into a series of events. For example, assume that tester 14 wished to test the scenario having the following events:
(1) Create meeting invitation
(2) An invitee accepts the invitation
(3) An invitee rejects the invitation

To this extent, an optional scenario system 36 could be provided. If provided, scenario system 36 aids tester 14 in compartmentalizing a scenario into a series of events. In one embodiment, scenario system 36 could provide tester 14 with any necessary interface pages for identifying a scenario and setting forth the scenario's corresponding events. In addition, scenario system 36 could be programmed to allow tester 14 to select a particular scenario from a list or the like. Once a particular scenario was selected, scenario system 36 could then display a list of all event(s) involved with that scenario for tester 14 to view and reference. Tester 14 could then select some or all of the events displayed in the list. This embodiment is especially helpful in the event that tester 14 does not recall all of the possible events that could be part of a particular scenario. For example, upon inputting/selecting the schedule meeting scenario, the following list of events could be displayed:
(1) Create meeting invitation
(2) An invitee accepts the invitation
(3) An invitee declines the invitation
(4) The meeting “Chair” adds an invitee to the invitation
(5) An invitee proposes a new meeting time
   This list could represent all possible events that could be part of a schedule meeting scenario, even though tester 14 might not wish to include all of these events in creating a scenario to test. Moreover, as will be further described below two different schedule meeting scenarios could have the same events, but arranged in a different order. Regardless, of the implementation, the general role of the optional scenario system 36 is to facilitate the compartmentalization of a single scenario into a series of events and/or to inform tester 14 of the different events that could comprise a given scenario.

Once tester 14 has identified a series of events that will comprise his/her desired scenario, tester 14 will utilize test case system 38 to prepare an actual test case/set for verifying the series. In preparing a test case, tester 14 will arrange the series of events into a desired order, and set forth the following for each event in the series: (1) an event type; (2) event information (i.e., a data package); and (3) a verification decision. Shown below is an illustrative test case.

{{CREATE_MEETING_INVITATION, {Jan. 2, 2004, {John Doe, Daisy Jones}, FALSE}}, {ACCEPT_MEETING, John Doe, TRUE}, {DECLINE_MEETING, Daisy Jones, TRUE}}

In the above test case, three events have been arranged in a particular order. Specifically, the three events are: (1) “create a meeting invitation;” (2) “invitee John Doe accepts the meeting invitation;” and (3) “invitee Daisy Jones declines the meeting invitation.” The event information adjacent each event specifies details about the particular event. For example, the event information for the “create a meeting invitation event” specifies that the meeting will be held on Jan. 2, 2004 and includes the invitees John Doe and Daisy Jones. The event information for the “accept meeting” event specifies that invitee John Doe accepts the meeting invitation.” Similarly, the event information for the “decline meeting” event specifies that invitee Daisy Jones declines the meeting invitation.

Lastly, tester 14 has included verification decisions for each event. In a typical embodiment, the verification decision is a Boolean expression such as TRUE or FALSE. However, it should be understood that the verification decision can take any known form. In any event, the verification decision states/expresses whether the particular event will be verified as part of the test. From the above test case, it can be seen that tester 14 wishes to verify only the latter two events, namely, “invitee John Does accepts the meeting invitation,” and “invitee Daisy Jones declines the meeting invitation.”

The use of a test case such as the above makes it extremely easy for tester 14 to not only create a scenario, but also to alter it. For example, in a later test, tester 14 could decide to verify the “create a meeting invitation event” simply by changing the verification decision to TRUE. Moreover, tester 14 could create a new scenario by switching the order of the events (e.g., the “accept meeting event” and the “decline meeting event”) and/or by changing the corresponding event information. For example, a new scenario could have invitee Daisy Jones accepting the meeting invitation and invitee John Doe declining the meeting invitation. Thus, a high level of expertise is not needed in creating test scenarios under the present invention.

In any event, once tester 14 has completed the test case, verification system 40 will perform the test accordingly. That is, the test case will be passed to verification system 40, which will execute the events, and then verify the events according to the event information and verification decision. In a typical embodiment, verification system 40 comprises an event handler that is a switch statement or list processor. Shown below is illustrative pseudo code representing a switch statement for the above illustrative scenario:
For each EventType
   Switch EventType
      case CREATE_MEETING_INVITATION
         check data package for valid data
         if data is valid pass to CreateMeetinglnvitation Function
         else return an error
      case ACCEPT_MEETING_INVITATION
         check data package for valid data
         if data is valid pass to CreateMeetinglnvitation Function
         else return an error
      case DECLINE_MEETING_INVITATION
         check data package for valid data
         if data is valid pass to CreateMeetinglnvitation Function
         else return an error
      default
         raise an error that the event passed is not (yet) supported
end for
   In verifying a performance of the appropriate events, verification system 40 will determine whether the events functioned as intended when executed. In executing the events, verification system 40 could coordinate with application 32 under a “test” condition so that actual users do not become confused (e.g., into believing that an actual meeting is being scheduled). Alternatively, verification system 40 could itself execute the events as defined in the test case. For example, verification system 40 could virtually create a meeting invitation for a meeting on Jan. 2, 2004 and communicate the same to users John Doe and Daisy Jones (which could be actual users, or hypothetical users created within verification system 40 for test purposes). Then, verification system 40 could have user John Doe accept the invitation and user Daisy Jones decline the invitation. As this was occurring, verification system 40 could monitor the events according to the verification decisions set forth in the test case to verify that the appropriate actions/responses were occurring. For example, in verifying whether the “invitee John Doe accepts meeting invitation” event functioned properly, verification system 40 will determine: (1) whether the meeting “Chair” (e.g., the person who created the meeting invitation) received an acceptance notice from John Doe; and (2) whether the meeting was added to invitee John Doe's calendar. Moreover, in verifying whether the “invitee Daisy Jones declines meeting invitation” event functioned as programmed, verification system 40 will determine: (1) whether the meeting “Chair” (e.g., the person who created the meeting invitation) received a decline notice from Daisy Jones; and (2) whether the meeting was left off of invitee Daisy Jones' calendar. If any of these items have not occurred, then verification for the event has failed. For example, if the meeting “Chair” never received the acceptance notice from invitee John Doe, then the “invitee John Doe accepts meeting invitation” event has failed.

Once the test has been completed, results could be presented to tester 14 via output system 42 in a graphical user interface or the like. The results can include success notifications for events that have been successfully verified and/or error messages for events that have not been successfully verified. Regardless, as can be seen, the present invention thus makes it extremely easy and efficient to test various scenarios. If a new event is desired to be verified, tester 14 need only include it within the text case with corresponding event information and a verification decision, and then ensure that a corresponding case statement is present for the event in the switch statement. Unlike previous systems, altering scenarios will not require the creation of an entirely new set of test code.

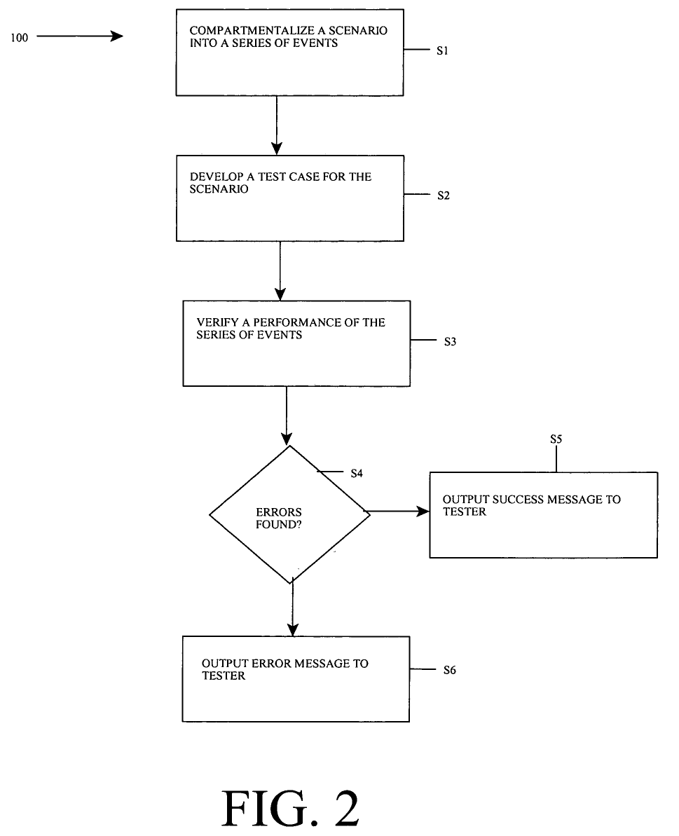

Referring now to FIG. 2, a method flow diagram 100 according to the present invention is shown. As depicted, first step S1 is to compartmentalize a scenario into a series of events. Second step S2 is to develop a test case for the scenario. As indicated above, this involves arranging the series of events into a desired order, and providing event information and a verification decision for each of the series of events. Third step S3 is to verify a performance of the series of events based on the event information and the verification decisions provided in the test case. If no errors are found in step S4, a success message is passed to the tester in step S5. Conversely, if errors are found in step S4, an error message is passed to the tester in Step S6.

It should be appreciated that the teachings of the present invention could be offered as a business method on a subscription or fee basis. For example, computer system 12 and/or testing system 34 could be created, maintained, supported and/or deployed by a service provider that offers the functions described herein for customers.

It should also be understood that the present invention can be realized in hardware, software, a propagated signal, or any combination thereof. Any kind of computer/server system(s)—or other apparatus adapted for carrying out the methods described herein—is suited. A typical combination of hardware and software could be a general purpose computer system with a computer program that, when loaded and executed, carries out the respective methods described herein. Alternatively, a specific use computer, containing specialized hardware for carrying out one or more of the functional tasks of the invention, could be utilized. The present invention can also be embedded in a computer program product or a propagated signal, which comprises all the respective features enabling the implementation of the methods described herein, and which—when loaded in a computer system—is able to carry out these methods. Computer program, propagated signal, software program, program, or software, in the present context mean any expression, in any language, code or notation, of a set of instructions intended to cause a system having an information processing capability to perform a particular function either directly or after either or both of the following: (a) conversion to another language, code or notation; and/or (b) reproduction in a different material form.

The foregoing description of the preferred embodiments of this invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims. For example, the depiction of testing system 34 in FIG. 1 is intended to be illustrative only.

I claim:

1. An event driven testing method, comprising:
compartmentalizing a scenario into a series of events;
developing a test case for the scenario by arranging the series of events into a desired order, and by providing event information and a verification decision for each of the series of events; and
verifying a performance of the series of events based on the event information and the verification decisions provided in the test case.

2. The event driven testing method of claim 1, wherein the scenario is an information technology (IT) scenario, and wherein the IT scenario is compartmentalized into a series of discrete IT events.

3. The event drive testing method of claim 1, wherein the verification decision provided for each of the series of events states whether each of the series of events will be verified during the verifying step.

4. The event driven testing method of claim 1, wherein the verifying step comprises testing the series of events based on the verification decisions to determine whether the series of events functions as intended.

5. The event driven testing method of claim 1, further comprising passing the test case to an event handler prior to the verifying step.

6. The event driven testing method of claim 5, wherein the event handler comprises a switch statement for processing the test case.

7. The event driven testing method of claim 1, further comprising:
developing a new test case by changing the desired order of the series of events; and
verifying a performance of the series of events using on the new test case.

8. An event driven testing system comprising:
a test case system for developing a test case for a scenario compartmentalized into a series of events by arranging the series of events into a desired order, and by providing event information and a verification decision for each of the series of events; and
a verification system for verifying a performance of the series of events based on the event information and the verification decisions provided in the test case.

9. The event drive testing system of claim 8, further comprising:
a scenario system for compartmentalizing the scenario into the series of events; and
an output system for outputting results of the verification.

10. The event driven testing system of claim 8, wherein the scenario is an information technology (IT) scenario, and wherein the IT scenario is compartmentalized into a series of discrete IT events.

11. The event drive testing system of claim 8, wherein the verification decision provided for each of the series of events states whether each of the series of events will be verified by the verification system.

12. The event driven testing system of claim 8, wherein the verification system tests the series of events based on the verification decisions to determine whether the series of events functions as intended.

13. The event driven testing system of claim 8, wherein the verification system comprises an event handler.

14. The event driven testing system of claim 13, wherein the event handler comprises a switch statement for processing the test case.

15. An event driven testing program product stored on a recordable medium, which when executed comprises:
program code for developing a test case for a scenario compartmentalized into a series of events by arranging the series of events into a desired order, and by providing event information and a verification decision for each of the series of events; and
program code for verifying a performance of the series of events based on the event information and the verification decisions provided in the test case.

16. The event driven testing program product of claim 15, further comprising:
program code for compartmentalizing the scenario into the series of events; and
program code for outputting results of the verification.

17. The event driven testing program product of claim 15, wherein the scenario is an information technology (IT) scenario, and wherein the IT scenario is compartmentalized into a series of discrete IT events.

18. The event drive testing program product of claim 15, wherein the verification decision provided for each of the series of events states whether each of the series of events will be verified by the program code for verifying.

19. The event driven testing program product of claim 15, wherein the program code for verifying tests the series of events based on the verification decisions to determine whether the series of events functions as intended.

20. The event driven testing program product of claim 15, wherein the verification system comprises an event handler.

21. The event driven testing program product of claim 20, wherein the event handler comprises a switch statement for processing the test case.

22. A system for deploying an event driving testing application, comprising:
a computer infrastructure being operable to:
develop a test case for a scenario compartmentalized into a series of events by arranging the series of events into a desired order, and by providing event information and a verification decision for each of the series of events; and
verify a performance of the series of events based on the event information and the verification decisions provided in the test case.

23. Computer software embodied in a propagated signal for event driving testing, the computer software comprising instructions to cause a computer system to perform the following functions:
develop a test case for a scenario compartmentalized into a series of events by arranging the series of events into a desired order, and by providing event information and a verification decision for each of the series of events; and
verify a performance of the series of events based on the event information and the verification decisions provided in the test case.
